(19) United States
(12) Patent Application Publication
(10) Pub. No.: US 2026/0331366 A1
(43) Pub. Date: Oct. 22, 2026

(54) Inductor Module for Power Electronics Assembly and Methods of Manufacturing

(71) Applicant: Infineon Technologies Austria AG, Villach (AT)

(72) Inventors: Kok Yau Chua, Melaka (MY); Sook Woon Chan, Semabok (MY); Joseph Victor Soosai Prakasam, Chennai (IN); Ibn'Asyura Zainuddin, Sungai Udang (MY)

(21) Appl. No.: 19/180,808

(22) Filed: Apr. 16, 2025

(51) Int. Cl. H01F 41/04; H01F 27/24; H01F 27/28; H05K 1/18

(52) U.S. Cl. CPC H01F 41/04; H01F 27/24; H01F 27/28; H05K 1/181; H05K 2201/1003

(57) ABSTRACT

A method of manufacturing an inductor module includes providing an inductor that comprises a conductor having a first end protruding from a first main face of a magnetic core and a second end protruding from a second main face of the magnetic core opposite the first main face; inserting the second end of the conductor into an opening of a metallic clip, wherein the metallic clip comprises a base having the opening that receives the second end of the conductor and a first leg extending from the base along a first side face of the magnetic core; and with the second end of the conductor inserted in the opening of the metallic clip, deforming the second end such that the inductor is free to move along an axis parallel to the first leg of the metallic clip.

### BACKGROUND

Increasing power demand of modern processors combined with variable and decreasing point-of-load voltages drives load currents to very high levels with current peaks of 1000 A and higher becoming common. In addition, the dynamic requirements on load jumps, specifically the sudden increase of load currents, are very challenging to address. As the capability of modern processors to perform additional computational calculations is mainly thermally limited, a precise regulation of the voltage at the interface to the processor becomes increasingly important. With the power dissipation of processors basically scaling with the square of the input voltage, a lowering of the input voltage closer to the threshold of catastrophic processor failure enables processors to run cooler and take additional computational tasks, making precise voltage regulation even more important.

Complications related to dimensional variations and constraints may arise when manufacturing a power electronics assembly such as a voltage regulator module for regulating the voltage at the interface to a processor. For example, dimensional variations emanating from manufacturing variability of the constituent components of the power electronics assembly may lead to difficulties in achieving reliable connections between respective components. In some instances, these dimensional variations may prevent the assembly from being completed, leading to increased manufacturing scrap.

Thus, there is a need for a solution that enables dimensional variations of constituent components to be accommodated when forming a power electronics assembly such as a voltage regulator module.

### SUMMARY

According to an embodiment of a method of manufacturing an inductor module, the method comprises: providing an inductor that comprises a conductor having a first end protruding from a first main face of a magnetic core and a second end protruding from a second main face of the magnetic core opposite the first main face; inserting the second end of the conductor into an opening of a metallic clip, wherein the metallic clip comprises a base having the opening that receives the second end of the conductor and a first leg extending from the base along a first side face of the magnetic core; and with the second end of the conductor inserted in the opening of the metallic clip, deforming the second end such that the inductor is free to move along an axis parallel to the first leg of the metallic clip, with the movement of the inductor along the axis being constrained between a first position delimited by the deformed second end of the conductor and a second position delimited by the second main face of the magnetic core.

According to an embodiment of an inductor module, the inductor module comprises: an inductor that comprises a conductor having a first end protruding from a first main face of a magnetic core and a second end protruding from a second main face of the magnetic core opposite the first main face; and a metallic clip that comprises a base having an opening that receives the second end of the conductor and a first leg extending from the base along a first side face of the magnetic core, wherein the second end of the conductor extends through the opening of the metallic clip and is deformed, such that the inductor is free to move along an axis parallel to the first leg of the metallic clip, with the movement of the inductor along the axis being constrained between a first position delimited by the deformed second end of the conductor and a second position delimited by the second main face of the magnetic core.

According to an embodiment of a method of manufacturing a power electronics assembly, the method comprises: aligning one or more inductor modules with a circuit board, wherein each of the one or more inductor modules comprise a metallic clip and an inductor, wherein a conductor of the inductor has a first end protruding from a first main face of a magnetic core of the inductor and a second end protruding from a second main face of the magnetic core opposite the first main face, wherein the metallic clip comprises a base having an opening which receives the second end of the conductor and a first leg extending from the base along a first side face of the magnetic core, wherein the second end of the conductor extends through the opening of the metallic clip and is deformed; attaching the first leg of the metallic clip and the first end of the conductor to the circuit board or a component mounted on the circuit board, wherein during the attaching, the inductor is free to move along an axis parallel to the first leg of the metallic clip, with the movement of the inductor along the axis being constrained between a first position delimited by the deformed second end of the conductor and a second position delimited by the second main face of the magnetic core; and after the attaching, fixing the deformed second end of the conductor to the base of the metallic clip.

According to an embodiment of a power electronics assembly, the power electronics assembly comprises: one or more inductor modules, wherein each of the one or more inductor modules comprise a metallic clip and an inductor, wherein a conductor of the inductor has a first end protruding from a first main face of a magnetic core of the inductor and a second end protruding from a second main face of the magnetic core opposite the first main face, wherein the metallic clip comprises a base having an opening which receives the second end of the conductor and a first leg extending from the base along a first side face of the magnetic core, wherein the second end of the conductor extends through the opening of the metallic clip and is deformed; and a circuit board, wherein the first leg of the metallic clip and the first end of the conductor are attached to the circuit board or a component mounted on the circuit board, wherein the deformed second end of the conductor is fixed to the base of the metallic clip and wider than the opening of the metallic clip.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A-1D illustrate views of an inductor module, according to embodiments.

FIG. 2 illustrates perspective views of an inductor and a metallic clip, according to an embodiment.

FIG. 3 illustrates a perspective view of an inductor module during assembly, according to an embodiment.

FIG. 4 illustrates a method for aligning one or more inductor modules with a circuit board, according to an embodiment.

FIG. 5 illustrates a method for attaching one or more inductor modules to a circuit board, according to an embodiment.

FIG. 6 illustrates a method for fixing a conductor of an inductor module to a metallic clip of the inductor module, according to an embodiment.

FIG. 7 illustrates a cross-sectional side view of a power electronics assembly, according to an embodiment.

### DETAILED DESCRIPTION

Described herein is an inductor module having an inductor and a metallic clip that are assembled to form a “swivel structure”. The “swivel structure” enables the inductor module to accommodate dimensional deviations (e.g., from manufacturing variability) when assembling the inductor module with another component. More specifically, utilizing an inductor module in a target application such as a power electronics assembly may include attaching each of the conductor and the metallic clip of the inductor module to a circuit board such as a printed circuit board (PCB), embedded chip substrate, embedded die substrate, etc. or to a component of the circuit board. Factors such as manufacturing variability may result in dimensions of the inductor module and/or the circuit board and/or components of the circuit board deviating from their as-designed values. When utilizing a standard inductor module, such dimensional deviations of the constituent components may prevent successful attachment of the inductor module to the circuit board. By contrast, the “swivel structure” of the inductor module disclosed herein allows the inductor and the metallic clip to move semi-independently relative to one another when attaching (e.g., soldering) the conductor and the metallic clip to respective components of the circuit board. This permitted relative movement of the inductor and the metallic clip may enable the inductor module to be successfully attached to the circuit board even when dimensions (e.g., a height) of one or more of the components that the inductor module is being attached to, or even dimensions of the inductor module itself, deviate from their as-designed values. As a result, the failure rate for attaching the inductor module to the circuit board may be reduced, potentially reducing manufacturing scrap.

Described next, with reference to the figures, are exemplary embodiments of the inductor module, a method of forming the inductor module, a method of assembling the inductor module with other components to form a power electronics assembly, and a power electronics assembly that includes the inductor module.

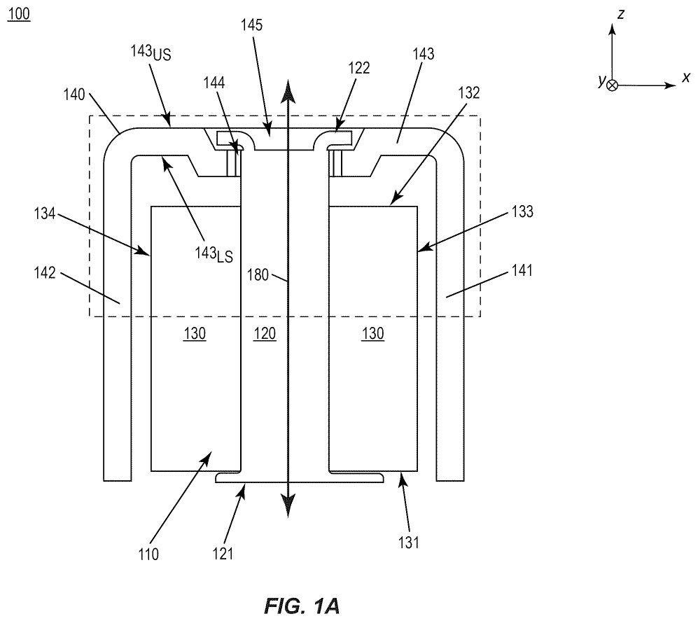

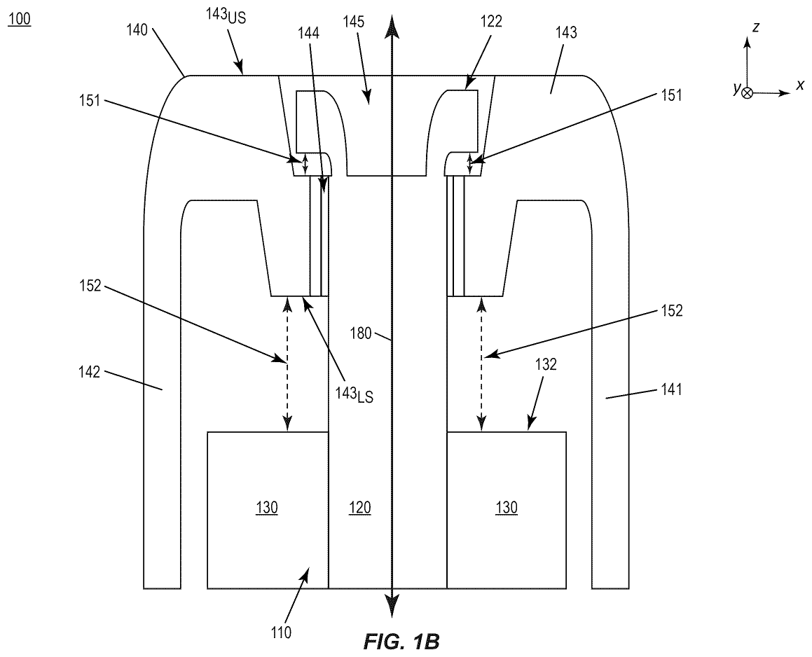

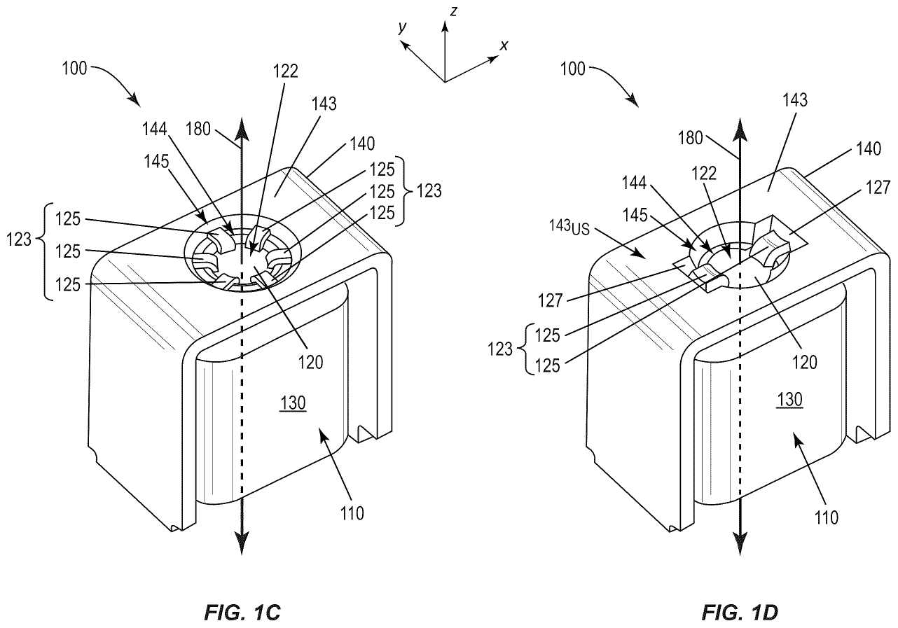

FIGS. 1A-1D illustrate views of an inductor module 100, according to embodiments. FIG. 1A illustrates a cross-sectional side view of the inductor module 100, according to an embodiment. FIG. 1B illustrates a partial cross-sectional side view of the inductor module 100, according to an embodiment. FIGS. 1C and 1D illustrate perspective views of the inductor module 100, according to embodiments.

The inductor module 100 includes an inductor 110 and a metallic clip 140. The inductor 110 includes a conductor 120 partly embedded in a magnetic core 130. A first end 121 of the conductor 120 protrudes from a first main face 131 of the magnetic core 130. A second end 122 of the conductor 120 protrudes from a second main face 132 of the magnetic core 130 opposite the first main face 131.

The metallic clip 140 includes a base 143. A first leg 141 of the metallic clip 140 extends from the base 143 along a first side face 133 of the magnetic core 130. A second leg 142 of the metallic clip 140 extends from the base 143 along a second side face 134 of the magnetic core 130 opposite the first side face 133. The first leg 141 and/or the second leg 142 may be oriented substantially perpendicular to the base 143. In this example, the metal clip 120 has a U-shape and covers the second main face 132 and the first and second side faces 133 and 134 of the magnetic core.

The base 143 of the metallic clip 140 has an opening 144 that receives the second end 122 of the conductor 120. The second end 122 of the conductor 120 extends through the opening 144 of the metallic clip 140 and is deformed (e.g., deformed outwardly past a perimeter of the opening 144) such that the deformed second end 122 of the conductor 120 is wider than the opening 144 of the metallic clip 140 (e.g., wider in the x and/or y dimensions). In this way, the deformed second end 122 of the conductor 120 is restricted from passing through the opening 144. The inductor 110 is thus fixed to the base 143 of the metallic clip 140 by the deformed second end 122 of the conductor 120 on an upper side 143_{US} of the base 143 and the magnetic core 130 on a lower side 143_{LS} of the base 143. In this example, the deformed second end 122 of the conductor is received by a recess 145 that is formed in the upper surface 143_{US} of the base 143 and is laterally coincident with the opening 144.

While the inductor 110 is fixed to the base 143 of the metallic clip 140, it is free to move along an axis 180 parallel to the first leg 141 of the metallic clip 140 (e.g., parallel to the z direction as illustrated). This principle of the inductor assembly 100 is illustrated in FIG. 1B, which illustrates an enlarged view of the portion of the inductor module 100 contained within the dashed window in FIG. 1A. The movement of the inductor 110 along the axis 180 is constrained between a first position 151 delimited by the deformed second end 122 of the conductor 120 and a second position 152 delimited by the second main face 132 of the magnetic core 130. That is, the inductor 110 can move along the axis 180 between a position where the deformed second end 122 is in contact with the metallic clip 140 (e.g., with a base of the recess 145) and a position where the second main face 132 of the magnetic core 130 is in contact with the metallic clip 140 (e.g., with the lower surface 143_{LS} of the base 143.

As illustrated in FIGS. 1C and 1D, the deformed second end 122 of the conductor 120 may include a flange 123 that effectuates the restriction of movement of the deformed second end 122 through the opening 144 of the metallic clip and thus, along with the magnetic core 130, constrains the movement of the inductor 110 along the axis 180. The flange 123 may have one or more features 125. In the examples of FIGS. 1C and 1D, the features 125 are implemented as metallic tabs 125 formed in the deformed second end 122 of the conductor 120 and are bent outwardly past a perimeter of the opening 144.

FIG. 1D illustrates an embodiment of the inductor module 100 in which the base 143 of the metallic clip 140 includes one or more features 127 configured to engage the deformed second end 122 of the conductor 120 and limit rotational movement of the inductor 110 about the axis 180. For example, the features 127 may be formed in the base 143 of the metallic clip 140 and configured to mate with the one or more features 125 of the flange 123 of the conductor 120. FIG. 1D illustrates one example in which the features 127 formed in the base 143 are implemented as corresponding notches 127 each sized to receive a metallic tab 125 of the flange 123. In this example, the notches 127 are merged with the recess 145 that is formed in an upper surface 143_{US} of the base 143. Examples in which the features 127 are formed in the opening 144 of the base 143 (e.g., along the perimeter of the opening 144) are contemplated.

The inductor module 100 illustrated in the embodiments of FIGS. 1A-1D can be characterized as a “swivel structure” that is formed by mating the inductor 110, and more specifically the second end 122 of the conductor, with the metallic clip 140. In this “swivel structure” arrangement, the inductor 110 is fixed to the metallic clip 140 but can have restricted movement along the axis 180 (e.g., within the constraints defined by the deformed end 122 of the conductor 120 and the magnetic core 130) and either free or restricted rotational movement about the axis 180. As will be discussed further with reference to subsequent embodiments, utilizing the inductor module 100 in a target application (e.g., a power electronics assembly) may include attaching each of the conductor 120 and the metallic clip 140 to a component (e.g., a metallization layer, terminal, node, pad, chip, etc.) of a circuit board such as a printed circuit board (PCB), embedded chip substrate, embedded die substrate, etc. This attachment may include soldering or otherwise adhering each of the conductor 120 and the first and/or second legs 141 and 142 of the metallic clip 140 to a respective component of the circuit board. The “swivel structure” of the inductor module 100 allows the inductor 110 and the metallic clip 140 to move semi-independently relative to one another when attaching (e.g., soldering) the conductor 120 and the metallic clip 140 (e.g., the first and/or second legs 141 and 142) to respective components of the circuit board. This permitted relative movement may enable the inductor module 100 to accommodate deviations from the as-designed heights of the respective components to which the conductor 120 and the metallic clip 140 are being attached. As a result, the failure rate for attaching the inductor module 100 to the assembly may be reduced, potentially reducing manufacturing scrap.

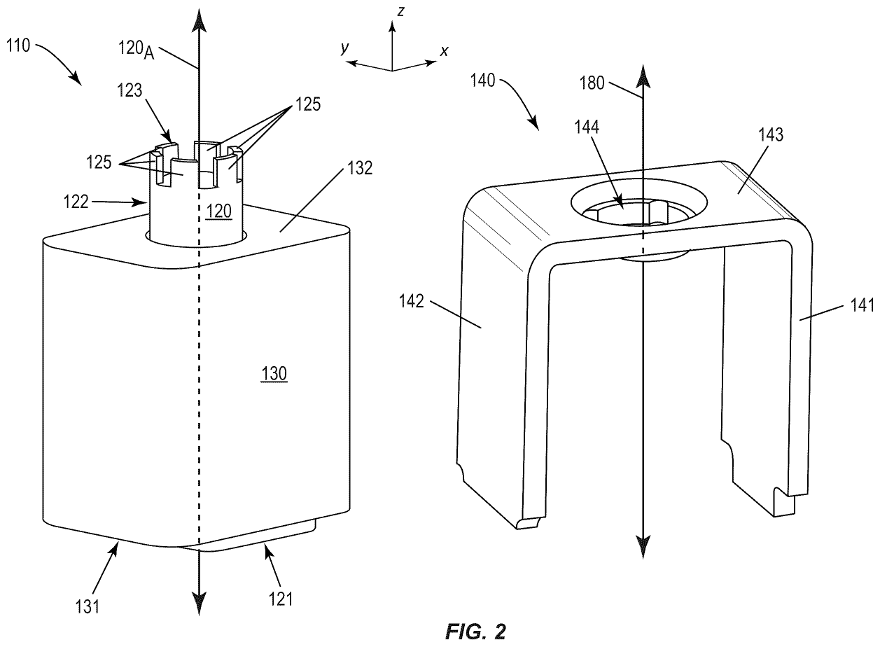

FIG. 2 illustrates perspective views of the inductor 110 and the metallic clip 140, according to embodiments. The inductor 110 and the metallic clip 140 may be provided unassembled as illustrated in FIG. 2 to assemble the inductor module 100. The magnetic core 130 of the inductor 110 may be formed from a suitable magnetic material, e.g. a ferromagnetic material such as iron. The conductor 120 of the inductor 110 may be formed from any suitable metal or other electrically conductive material. The conductor 120 may have a cylindrical or cuboidal shape extending along a conductor axis 120_{A}. The metallic clip 140 may be formed from copper and/or any other metal or metal alloy. The first leg 141, the second leg 142, and the base 143 of the metallic clip 140 may be formed as a single contiguous unit, e.g., by stamping, bending, etc. While not specifically illustrated in FIG. 2, the metallic clip 140 may be formed with one or more features in the base 143 (e.g., the features 127 of FIG. 1D) that are configured to limit rotational movement of the inductor 110 about the axis 180 when the inductor 110 is assembled with the metallic clip 140.

The inductor 110 is formed and provided with the second end 122 of the conductor 120 in an undeformed state. In the example of FIG. 2, the conductor 120 is formed and provided with the flange 123 having metallic tabs 125 arranged at the second end 122. The undeformed state of the second end 122 in this example is characterized by the metallic tabs 125 of the flange 123 being oriented substantially parallel to the conductor axis 120_{A} rather than being bent outwardly past the perimeter of the opening 144 as they are in the assembled inductor module 100 illustrated in FIGS. 1A-1D.

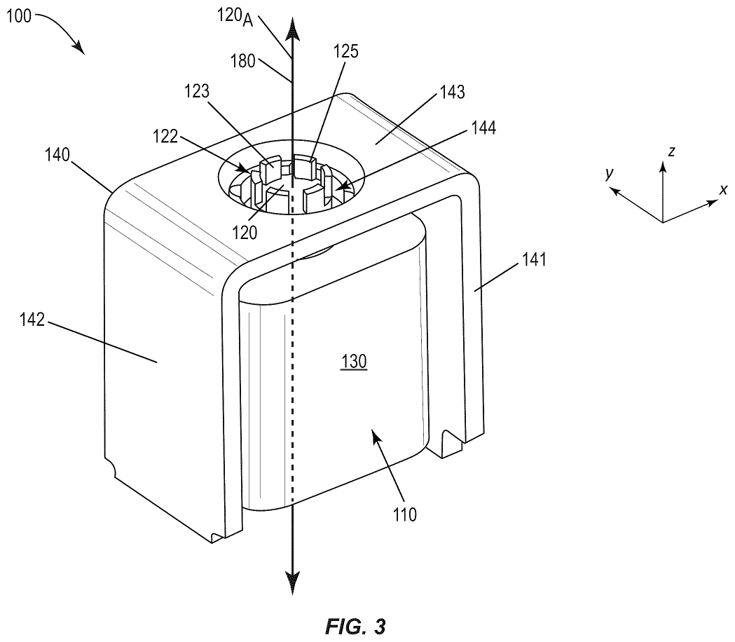

FIG. 3 illustrates a perspective view of the inductor module 100 during assembly, according to an embodiment. The inductor 110 and the metallic clip 140 may be assembled to form the partially assembled inductor module 100 of FIG. 3 by inserting the undeformed second end 122 of the conductor 120 into the opening 144 of the metallic clip 140. When assembling the inductor 110 and the metallic clip 140 in this manner, the conductor axis 120_{A} may be substantially aligned with the axis 180. After inserting the undeformed second end 122 of the conductor 120 into the opening 144 of the metallic clip, the inductor 110 may be fixed to the base 143 of the metallic clip 140 by deforming the second end 122, e.g. bending the metallic tabs 125 of the flange outwardly to form the deformed second end 122 illustrated in FIGS. 1A-1D. Deforming the second end 122 of the conductor 120 may include stamping the second end 122 of the conductor 120 (e.g., stamping the flange 123 to bend the metallic tabs 125 outwardly past the perimeter of the opening 144).

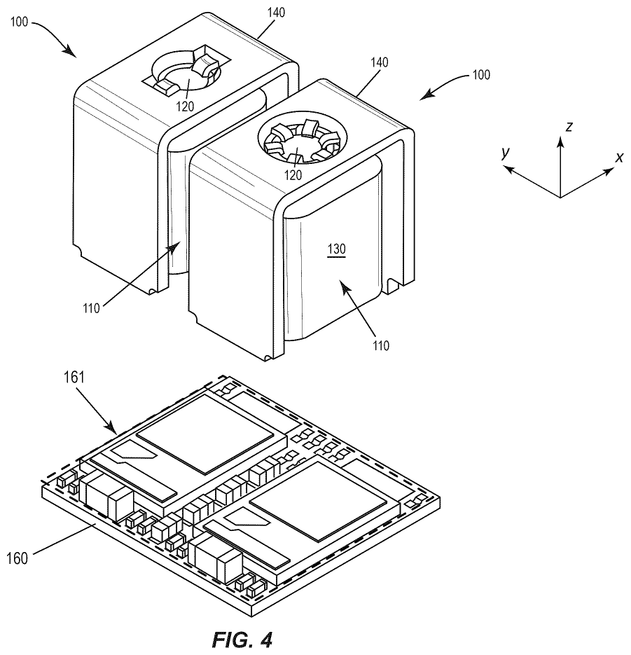

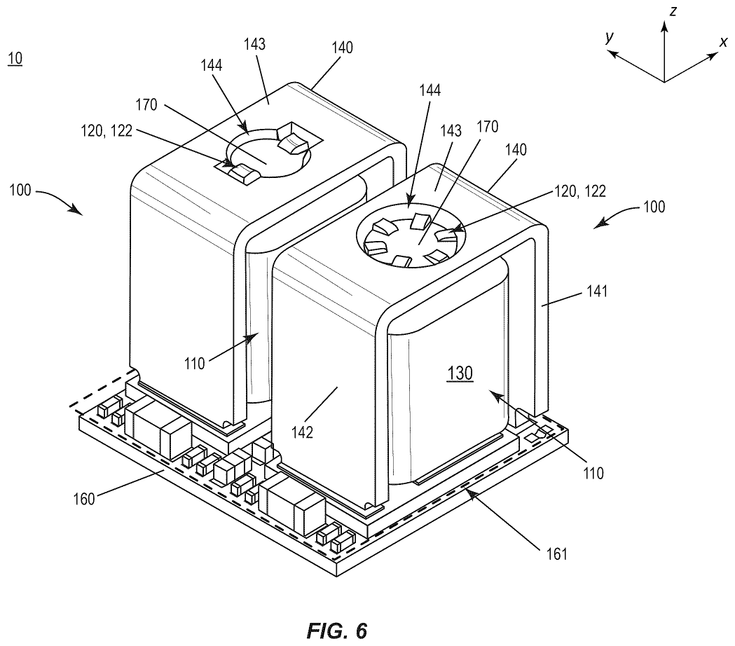

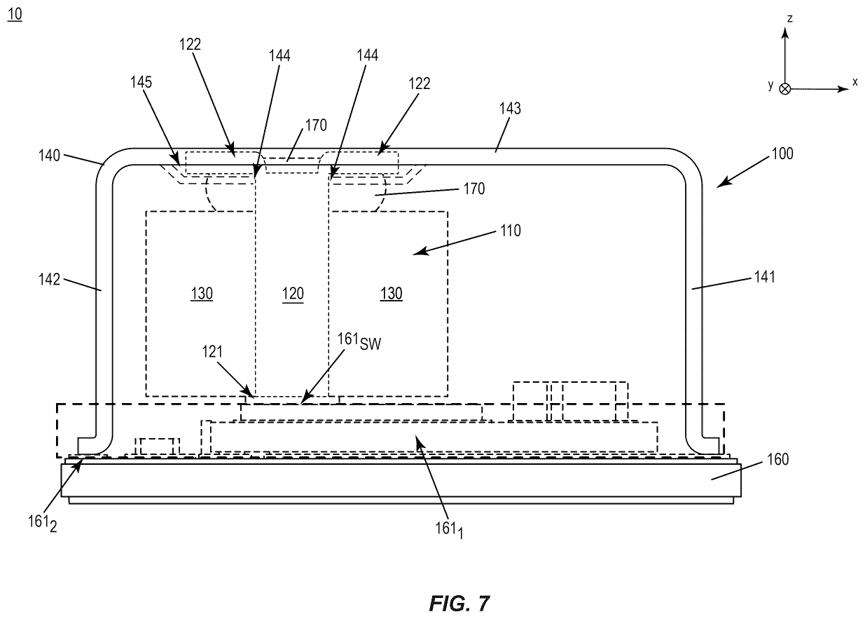

FIGS. 4-6 illustrate a method for assembling the inductor module 100 with other components to form a power electronics assembly 10. Embodiments of the completed power electronics assembly 10 are illustrated in FIGS. 6 and 7. The power electronics assembly 10 may be, for example, a voltage regulator module (e.g., a DC-DC converter such as a buck converter) that is configured receive an input voltage (e.g., from a power supply) and deliver a point-of-load voltage to a processor or other load.

FIG. 4 illustrates a method for aligning one or more inductor modules 100 with a circuit board 160, according to an embodiment. While FIG. 4 illustrates inductor modules 100 having separate metallic clips 140, examples in which an inductor module 100 includes two or more inductors 110 fixed to a common metallic clip 140 are contemplated. The circuit board 160 may be a PCB, embedded chip substrate, embedded die substrate, etc. The circuit board 160 includes a plurality of components 161. The components 161 may include one or more metallization layers, metallic traces, nodes, terminals, contact pads, vias, interconnects, substrates, passive components (e.g., capacitors, resistors), active components (e.g., transistor dies such as MOSFET, BJT, and/or IGBT dies), surface-mounted dies and/or chips, embedded dies and/or chips, drivers, controllers, sense elements, heat sinks, etc. Multiple of the components 161 may be arranged to form all or part of a circuit such as a power stage, a DC/AC inverter, a DC/DC converter, an AC/DC converter, a DC/AC converter, an AC/AC converter, a multi-phase inverter, an H-bridge, motor driver, etc. Each inductor 110 and metallic clip 140 (e.g., the first and second legs 141 and 142 of each metallic clip 140) may be aligned with one or more components 161 of the circuit board 160 for subsequent attachment to the respective component(s) 161. The alignment of the inductor module(s) 100 with the circuit board 160 and the subsequent placement on the circuit board 160 for attachment may be completed with a pick-and-place tool or by other means.

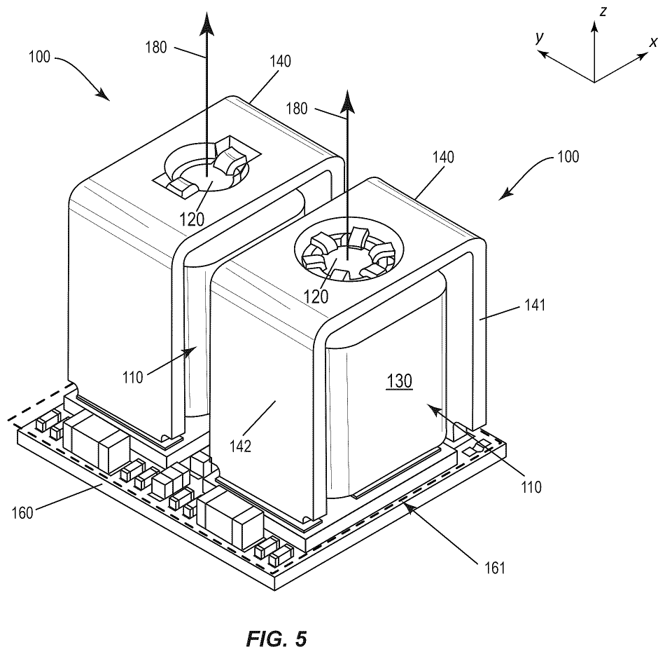

FIG. 5 illustrates a method for attaching one or more inductor modules 100 to the circuit board 160, according to an embodiment. Each of the inductor 110 and the metallic clip 140 may be attached to one or more components 161 of the circuit board 160, e.g., by soldering or other means (e.g., an electrically conductive adhesive). The first end 121 (not illustrated in FIG. 5) of the conductor 120 may, for example, be attached (e.g., soldered) to a switch node of a power stage formed from multiple of the components 161 of the circuit board 160. For example, the switch node may be a node between a high-side transistor and a low-side transistor of a half bridge inverter. The first leg 141 or second leg 142 of the metallic clip 140 may be attached (e.g., soldered) to a power output node of the circuit board. The first leg 141 or second leg 142 of the metallic clip 140 may be attached (e.g., soldered) to a metallization layer (e.g., a metal island) of the circuit board 160.

During the attaching of the inductor module(s) 100 to the circuit board 160, each inductor 110 is free to move along the axis 180. The inductor 110 may be moved along the axis 180 and, in some instances, may be rotated about the axis 180. Moving the inductor 110 relative to the metallic clip 140 when attaching the inductor module 100 to the circuit board 160 may enable the attachment of the inductor module 100 to be completed even when dimensions (e.g., a height) of one or more of the components 161 that the inductor module 100 is being attached to, or even dimensions of the inductor module 100 itself, deviate from their as-designed values. Such deviations from as-designed dimensions may result from manufacturing variability, and utilizing the inductor module 100 of the present disclosure when forming the power electronics assembly 10 may enable the process of attaching the inductor module(s) 100 to the circuit board 160 to accommodate such manufacturing variability while still achieving successful attachment of the inductor module(s) 100, potentially reducing manufacturing scrap.

FIG. 6 illustrates a method for fixing the conductor 110 of the inductor module 100 to the metallic clip 140 of the inductor module 100, according to an embodiment. After attaching the inductor module(s) 100 to the circuit board 160 (e.g., as illustrated in FIG. 5), the deformed second end 122 of the conductor 120 of each inductor 110 is fixed to the base 143 of the metallic clip 140. Fixing the conductor 120 to the base 143 may include securing the deformed second end 122 of the conductor 120 to the base 143 using a securing element 170. The securing element 170 may, for example, be a solder, an adhesive, an encapsulant, a fastener, a clip, etc. At this juncture, the assembly of the inductor module(s) 100 and the circuit board 160, along with its components 161, constitute the power electronics assembly 10.

FIG. 7 illustrates a cross-sectional side view of the power electronics assembly 10, according to an embodiment. The power electronics assembly 10 of FIG. 7 may be a voltage regulator module (e.g., a DC-DC converter such as a buck converter) that is configured receive an input voltage (e.g., from a power supply) and deliver a point-of-load voltage to a processor or other load.

The first end 121 of the conductor 120 is attached (e.g., soldered, welded, sintered, etc.) to a first component 161₁ of the circuit board 160. The inductor 110 and the first component 161₁ may form a power stage of the power electronics assembly 10. The first component 161₁ may, for example, include one or more power switches (e.g., MOSFETs) attached to or embedded in a substrate and electrically connected in series at a switch node 161_{SW}. For example, two power switches of the first component 161₁ may be connected in a half-bridge configuration at the switch node 161_{SW}, where a first power switch is a high-side switch that acts as a control switch and a second switch is a low-side switch that acts as a synchronous rectification switch. The circuit may form a synchronous buck converter receiving an input voltage from an input power terminal (e.g., formed in the circuit board 160) and being coupled to the inductor 110 at the switch node 161_{SW}. The first end 121 of the conductor 120 may be attached to the switch node 161_{SW} of the first component 161₁. The second leg 142 of the metallic clip 140 is attached (e.g., soldered, welded, sintered, etc.) to a second component 161₂ of the circuit board 160, which may be electrically coupled to a power output terminal, or may itself form a power output terminal of the power electronics assembly 10. The power stage may thus receive an input voltage from a power input terminal and output a phase current at a switch node 161_{SW} to the conductor 120. The current may flow through the conductor 120, the securing element 170, the metallic clip 140, and the second component 161₂ of the circuit board 160, and the power electronics assembly 10 may deliver power to a load from the power output terminal.

Although the present disclosure is not so limited, the following numbered examples demonstrate one or more aspects of the disclosure.

Example 1. A method of manufacturing an inductor module, the method comprising: providing an inductor that comprises a conductor having a first end protruding from a first main face of a magnetic core and a second end protruding from a second main face of the magnetic core opposite the first main face; inserting the second end of the conductor into an opening of a metallic clip, wherein the metallic clip comprises a base having the opening that receives the second end of the conductor and a first leg extending from the base along a first side face of the magnetic core; and with the second end of the conductor inserted in the opening of the metallic clip, deforming the second end such that the inductor is free to move along an axis parallel to the first leg of the metallic clip, with the movement of the inductor along the axis being constrained between a first position delimited by the deformed second end of the conductor and a second position delimited by the second main face of the magnetic core.

Example 2. The method of example 1, further comprising: limiting rotational movement of the inductor about the axis, wherein limiting rotational movement of the inductor about the axis comprises: forming a flange having one or more features arranged at the deformed second end of the conductor; and forming one or more features in the base of the metallic clip and configured to mate with the one or more features of the flange.

Example 3. The method of example 1 or 2, wherein the base of the metallic clip includes one or more features configured to engage the deformed second end of the conductor and limit rotational movement of the inductor about the axis.

Example 4. The method of any of examples 1 through 3, wherein deforming the second end of the conductor comprises stamping the second end of the conductor.

Example 5. The method of any of examples 1 through 4, further comprising: forming one or more features in the base of the metallic clip, wherein the one or more features are configured to limit rotational movement of the inductor about the axis.

Example 6. An inductor module, comprising: an inductor that comprises a conductor having a first end protruding from a first main face of a magnetic core and a second end protruding from a second main face of the magnetic core opposite the first main face; and a metallic clip that comprises a base having an opening that receives the second end of the conductor and a first leg extending from the base along a first side face of the magnetic core, wherein the second end of the conductor extends through the opening of the metallic clip and is deformed, such that the inductor is free to move along an axis parallel to the first leg of the metallic clip, with the movement of the inductor along the axis being constrained between a first position delimited by the deformed second end of the conductor and a second position delimited by the second main face of the magnetic core.

Example 7. The inductor module of example 6, wherein the deformed second end of the conductor includes a flange having one or more features, and wherein the base of the metallic clip includes one or more features configured to mate with the one or more features of the flange and limit rotational movement of the inductor about the axis.

Example 8. The inductor module of example 7, wherein the one or more features of the flange include at least one metallic tab formed in the deformed second end of the conductor, and wherein the one or more features of the base of the metallic clip include a corresponding notch sized to receive each metallic tab of the flange.

Example 9. The inductor module of any of examples 6 through 8, wherein the base of the metallic clip includes one or more features configured to engage the deformed second end of the conductor and limit rotational movement of the inductor about the axis.

Example 10. The inductor module of any of examples 6 through 9, wherein the metallic clip further comprises a second leg extending from the base along a second side face of the magnetic core opposite the first side face.

Example 11. A method of manufacturing a power electronics assembly, the method comprising: aligning one or more inductor modules with a circuit board, wherein each of the one or more inductor modules comprise a metallic clip and an inductor, wherein a conductor of the inductor has a first end protruding from a first main face of a magnetic core of the inductor and a second end protruding from a second main face of the magnetic core opposite the first main face, wherein the metallic clip comprises a base having an opening which receives the second end of the conductor and a first leg extending from the base along a first side face of the magnetic core, wherein the second end of the conductor extends through the opening of the metallic clip and is deformed; attaching the first leg of the metallic clip and the first end of the conductor to the circuit board or a component mounted on the circuit board, wherein during the attaching, the inductor is free to move along an axis parallel to the first leg of the metallic clip, with the movement of the inductor along the axis being constrained between a first position delimited by the deformed second end of the conductor and a second position delimited by the second main face of the magnetic core; and after the attaching, fixing the deformed second end of the conductor to the base of the metallic clip.

Example 12. The method of example 11, wherein the metallic clip further comprises a second leg extending from the base along a second side face of the magnetic core opposite the first side face, and wherein the attaching further comprises attaching the second leg of the metallic clip to the circuit board or a component mounted on the circuit board.

Example 13. The method of example 11 or 12, wherein the fixing comprises securing the deformed second end of the conductor to the base using a securing element.

Example 14. The method of example 13, wherein the securing element is selected from the group consisting of solder, an adhesive, an encapsulant, and a fastener.

Example 15. The method of any of examples 11 through 14, further comprising: during the attaching, moving the inductor along the axis.

Example 16. The method of any of examples 11 through 15, further comprising: during the attaching, rotating the inductor about the axis.

Example 17. A power electronics assembly, comprising: one or more inductor modules, wherein each of the one or more inductor modules comprise a metallic clip and an inductor, wherein a conductor of the inductor has a first end protruding from a first main face of a magnetic core of the inductor and a second end protruding from a second main face of the magnetic core opposite the first main face, wherein the metallic clip comprises a base having an opening which receives the second end of the conductor and a first leg extending from the base along a first side face of the magnetic core, wherein the second end of the conductor extends through the opening of the metallic clip and is deformed; and a circuit board, wherein the first leg of the metallic clip and the first end of the conductor are attached to the circuit board or a component mounted on the circuit board, wherein the deformed second end of the conductor is fixed to the base of the metallic clip and wider than the opening of the metallic clip.

Example 18. The power electronics assembly of example 17, wherein the metallic clip further comprises a second leg extending from the base along a second side face of the magnetic core opposite the first side face, and wherein the second leg of the metallic clip is attached to the circuit board or a component mounted on the circuit board.

Example 19. The power electronics assembly of example 17 or 18, further comprising: wherein the deformed second end of the conductor is fixed to the base of the metallic clip by a securing element.

Example 20. The power electronics assembly of example 19, wherein the securing element is selected from the group consisting of solder, an adhesive, an encapsulant, and a fastener.

Example 21. The power electronics assembly of any of examples 17 through 20, wherein the deformed second end of the conductor includes a flange having one or more features, and wherein the base of the metallic clip includes one or more features configured to mate with the one or more features of the flange and limit rotational movement of the inductor about an axis parallel to the first leg of the metallic clip.

Example 22. The power electronics assembly of any of examples 17 through 21, wherein the base of the metallic clip includes one or more features configured to engage the deformed second end of the conductor and limit rotational movement of the inductor about the axis.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing an inductor module, the method comprising:
providing an inductor that comprises a conductor having a first end protruding from a first main face of a magnetic core and a second end protruding from a second main face of the magnetic core opposite the first main face;
inserting the second end of the conductor into an opening of a metallic clip, wherein the metallic clip comprises a base having the opening that receives the second end of the conductor and a first leg extending from the base along a first side face of the magnetic core; and
with the second end of the conductor inserted in the opening of the metallic clip, deforming the second end such that the inductor is free to move along an axis parallel to the first leg of the metallic clip, with the movement of the inductor along the axis being constrained between a first position delimited by the deformed second end of the conductor and a second position delimited by the second main face of the magnetic core.

2. The method of claim 1, further comprising:
limiting rotational movement of the inductor about the axis,
wherein limiting rotational movement of the inductor about the axis comprises:
forming a flange having one or more features arranged at the deformed second end of the conductor; and
forming one or more features in the base of the metallic clip and configured to mate with the one or more features of the flange.

3. The method of claim 1, wherein the base of the metallic clip includes one or more features configured to engage the deformed second end of the conductor and limit rotational movement of the inductor about the axis.

4. The method of claim 1, wherein deforming the second end of the conductor comprises stamping the second end of the conductor.

5. The method of claim 1, further comprising:
forming one or more features in the base of the metallic clip, wherein the one or more features are configured to limit rotational movement of the inductor about the axis.

6. An inductor module, comprising:
an inductor that comprises a conductor having a first end protruding from a first main face of a magnetic core and a second end protruding from a second main face of the magnetic core opposite the first main face; and
a metallic clip that comprises a base having an opening that receives the second end of the conductor and a first leg extending from the base along a first side face of the magnetic core,
wherein the second end of the conductor extends through the opening of the metallic clip and is deformed, such that the inductor is free to move along an axis parallel to the first leg of the metallic clip, with the movement of the inductor along the axis being constrained between a first position delimited by the deformed second end of the conductor and a second position delimited by the second main face of the magnetic core.

7. The inductor module of claim 6, wherein the deformed second end of the conductor includes a flange having one or more features, and wherein the base of the metallic clip includes one or more features configured to mate with the one or more features of the flange and limit rotational movement of the inductor about the axis.

8. The inductor module of claim 7, wherein the one or more features of the flange include at least one metallic tab formed in the deformed second end of the conductor, and wherein the one or more features of the base of the metallic clip include a corresponding notch sized to receive each metallic tab of the flange.

9. The inductor module of claim 6, wherein the base of the metallic clip includes one or more features configured to engage the deformed second end of the conductor and limit rotational movement of the inductor about the axis.

10. The inductor module of claim 6, wherein the metallic clip further comprises a second leg extending from the base along a second side face of the magnetic core opposite the first side face.

11. A method of manufacturing a power electronics assembly, the method comprising:
aligning one or more inductor modules with a circuit board, wherein each of the one or more inductor modules comprise a metallic clip and an inductor, wherein a conductor of the inductor has a first end protruding from a first main face of a magnetic core of the inductor and a second end protruding from a second main face of the magnetic core opposite the first main face, wherein the metallic clip comprises a base having an opening which receives the second end of the conductor and a first leg extending from the base along a first side face of the magnetic core, wherein the second end of the conductor extends through the opening of the metallic clip and is deformed;
attaching the first leg of the metallic clip and the first end of the conductor to the circuit board or a component mounted on the circuit board, wherein during the attaching, the inductor is free to move along an axis parallel to the first leg of the metallic clip, with the movement of the inductor along the axis being constrained between a first position delimited by the deformed second end of the conductor and a second position delimited by the second main face of the magnetic core; and
after the attaching, fixing the deformed second end of the conductor to the base of the metallic clip.

12. The method of claim 11, wherein the metallic clip further comprises a second leg extending from the base along a second side face of the magnetic core opposite the first side face, and wherein the attaching further comprises attaching the second leg of the metallic clip to the circuit board or a component mounted on the circuit board.

13. The method of claim 11, wherein the fixing comprises securing the deformed second end of the conductor to the base using a securing element.

14. The method of claim 13, wherein the securing element is selected from the group consisting of solder, an adhesive, an encapsulant, and a fastener.

15. The method of claim 11, further comprising:
during the attaching, moving the inductor along the axis.

16. The method of claim 11, further comprising:
during the attaching, rotating the inductor about the axis.

17. A power electronics assembly, comprising:
one or more inductor modules, wherein each of the one or more inductor modules comprise a metallic clip and an inductor, wherein a conductor of the inductor has a first end protruding from a first main face of a magnetic core of the inductor and a second end protruding from a second main face of the magnetic core opposite the first main face, wherein the metallic clip comprises a base having an opening which receives the second end of the conductor and a first leg extending from the base along a first side face of the magnetic core, wherein the second end of the conductor extends through the opening of the metallic clip and is deformed; and
a circuit board, wherein the first leg of the metallic clip and the first end of the conductor are attached to the circuit board or a component mounted on the circuit board,
wherein the deformed second end of the conductor is fixed to the base of the metallic clip and wider than the opening of the metallic clip.

18. The power electronics assembly of claim 17, wherein the metallic clip further comprises a second leg extending from the base along a second side face of the magnetic core opposite the first side face, and wherein the second leg of the metallic clip is attached to the circuit board or a component mounted on the circuit board.

19. The power electronics assembly of claim 17, further comprising:
wherein the deformed second end of the conductor is fixed to the base of the metallic clip by a securing element.

20. The power electronics assembly of claim 19, wherein the securing element is selected from the group consisting of solder, an adhesive, an encapsulant, and a fastener.

21. The power electronics assembly of claim 17, wherein the deformed second end of the conductor includes a flange having one or more features, and wherein the base of the metallic clip includes one or more features configured to mate with the one or more features of the flange and limit rotational movement of the inductor about an axis parallel to the first leg of the metallic clip.

22. The power electronics assembly of claim 17, wherein the base of the metallic clip includes one or more features configured to engage the deformed second end of the conductor and limit rotational movement of the inductor about the axis.
